(19) United States
(12) Patent Application Publication
(10) Pub. No.: US 2013/0156949 A1
(43) Pub. Date: Jun. 20, 2013

(54) METHODS OF FABRICATING POROUS MEDIA AND INORGANIC SELECTIVE MEMBRANE

(71) Applicants: Meng-Chang Lin, Taichung City (TW); Yu-Li Lin, Chiayi City (TW); Yen-Hsun Chi, Taitung County (TW); Ting-Wei Huang, Hsinchu City (TW)

(72) Inventors: Meng-Chang Lin, Taichung City (TW); Yu-Li Lin, Chiayi City (TW); Yen-Hsun Chi, Taitung County (TW); Ting-Wei Huang, Hsinchu City (TW)

(73) Assignee: INDUSTRIAL TECHNOLOGY RESEARCH INSTITUTE, Hsinchu (TW)

(21) Appl. No.: 13/476,024

(22) Filed: May 21, 2012

(30) Foreign Application Priority Data
Dec. 16, 2011 (TW) 100146913

(51) Int. Cl. B05D 7/14; B05D 1/18; C23C 16/06; C25D 7/06

(52) U.S. Cl. 427/247; 205/150

(57) ABSTRACT

A method of fabricating a porous media is provided. In the method, a metal mesh is provided. The metal mesh includes interlaced metal wires, and first holes are formed among the metal wires. An area of each first hole ranges from 1 μm² to 10,000 μm², and an area error between the first holes is less than 5%. A metal layer covers the metal wires, so as to form the porous media with second holes. By controlling the thickness of the metal layer, an area of each second hole is reduced to 0.01 μm² to 1 μm², and an area error between the second holes is less than 5%.

### CROSS-REFERENCE TO RELATED APPLICATION

This application claims the priority benefit of Taiwan application serial no. 100146913, filed on Dec. 16, 2011. The entirety of the above-mentioned patent application is hereby incorporated by reference herein and made a part of this specification.

### TECHNICAL FIELD

The disclosure relates to a method of fabricating a porous media, and particularly relates to a method of fabricating a porous media that can be applied to an inorganic gas selective membrane.

### BACKGROUND

Currently, the common purification techniques applying for processing by-product hydrogen from the fabricating processes of petrochemical industries include pressure swing adsorption (PSA), freezing, alloy adsorption, and membrane separation. Among these techniques, using membrane filtration to separate hydrogen not only saves energy but also allows continuous action; in addition, catalysts may be introduced into filtration membranes for catalytic reforming to increase the production of hydrogen gas. Filtration membranes may be classified into two groups: inorganic filtration membranes and organic filtration membranes; from the results of related literature, it is found that the inorganic membranes have more potential for development than the organic membranes because compared to the organic membranes, the inorganic membranes are more capable of tolerating harsh conditions. Among the inorganic membranes, palladium (Pd) is an inorganic metal membrane that is mainly studied. Specifically, Pd is a precious metal with a strong affinity to hydrogen. It was first discovered in 1863 that hydrogen would permeate through transition metals by Deville and Troost, who discovered during experiments that iron and platinum (Pt), which are transition metals, had the function of hydrogen adsorption. Soon after, in 1866, Graham, when performing a similar experiment, discovered that H₂ was separated from gas mixtures on some surface regions of Pd, where the flux of hydrogen gas permeation was more rapid.

In recent years, due to the rising consciousness of environmental protection, membrane reactors are valued generally in the scientific community; therefore, the concept that Pd is used as a membrane is proposed, and studies regarding Pd membranes and alloys thereof for hydrogen gas separation are widely performed. Compared to other membrane reactors, Pd membrane reactors have higher permeation selectivity for hydrogen, and the purity of the permeating hydrogen gas is above 99%. The collected hydrogen gas may not only be used for industrial purposes but also be burned as fuels without other purification devices. In addition, since Pd membrane reactors have higher permeation selectivity for hydrogen than other membrane reactors, the Pd membrane reactors become one of the popular research topics.

The thicker the Pd membrane through which hydrogen gas permeates is, the better the effect of purification or separation is. However, the speed of hydrogen gas permeating through a Pd membrane is inversely proportional to the thickness of the Pd membrane. If the Pd membrane is too thick, the speed of hydrogen permeation decreases; therefore, the Pd membrane cannot be too thick. In contrast, if the Pd membrane is too thin, its mechanical strength is insufficient, and cracks are liable to occur under the pressure generated during gas filtration. However, reducing the thickness of the Pd membrane not only reduces the using amount of Pd metals and the system costs but also achieves great performance. Therefore, a Pd membrane is often covered on a hard media, which may bear a great stress and reduce the using amount of Pd and the costs at the same time. Common supporting media are porous glass, porous α-Al₂O₃, ceramics, or 316 porous stainless steel (hereinafter referred to as 316 PSS) fabricated by Pall Corporation or Mott Corporation in the US.

Compared to porous glass, porous α-Al₂O₃, and ceramics, using 316 PSS as supporting media for a Pd membrane has advantages, such as higher pressure resistance, good thermal shock resistance, and ease of being soldered and assembled. However, when using a 316 PSS as supporting media for a 10-μm-thick Pd membrane, the flux of hydrogen gas of 316 PSS/Pd is only about 3 cc/min·cm². By contrast, the flux of hydrogen gas may reach 42 cc/min·cm² when hydrogen gas permeation is performed directly with only a Pd membrane material with a thickness of 10 μm. In light of the above, 316 PSS is the main reason that causes the flux of hydrogen gas to decrease and prevents the Pd membrane material itself from presenting the property of a high flux of hydrogen gas. In addition, 316 PSS not only limits the flux of hydrogen gas of the Pd membrane material but also leads to interdiffusion of metal atoms between the Pd membrane and 316 PSS at a high temperature. When the Pd membrane is alloyed with elements with poor hydrogen permeation, such as Fe, Ni, and Cr (main elements in 316 PSS), the hydrogen permeation ability of the Pd membrane material will decrease, which causes the service life of the Pd membrane to decrease. Furthermore, currently, the main suppliers of 316 PSS media are in the United States and Japan, and 316 PSS is a restrictive product and is very expensive with a current price up to US$ 9,713/m².

### SUMMARY

The disclosure provides a method of fabricating a porous media, and the porous media has a high helium flux and interdiffusion resistance at a high temperature and may be made with low costs and applied as a supporting media for an inorganic hydrogen selective membrane.

The disclosure further provides a method of fabricating an inorganic selective membrane; the formed inorganic selective membrane has a high helium flux and interdiffusion resistance at a high temperature and may be made with low costs.

The disclosure proposes a method of fabricating a porous media. A metal mesh is provided, and the metal mesh is formed by interlacing metal wires, so that first holes are formed among the metal wires. An area of each of the first holes in the metal mesh is 1 μm² to 10,000 m², and an area error between the first holes is less than 5%. A metal layer is used to cover the metal wires, so as to form the porous media with second holes. By controlling the thickness of the metal layer, an area of each of the second holes is reduced to 0.01 μm² to 1 μm², and an area error between the second holes is less than 5%.

The disclosure further proposes a method of fabricating an inorganic selective membrane, including providing the above-mentioned porous media and forming a gas selective membrane thereon.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a top view illustrating a porous media according to an embodiment of the disclosure.

FIG. 2 is a schematic cross-sectional view illustrating a porous media according to an embodiment of the disclosure.

FIG. 3 is a schematic cross-sectional view illustrating an inorganic selective membrane according to an embodiment of the disclosure.

FIG. 4A is a scanning electron microscope (SEM) microstructure photograph of the stainless steel mesh of Example 1 of the disclosure.

FIG. 4B is a SEM microstructure photograph of the porous material of Example 1 of the disclosure.

FIG. 5A is a SEM microstructure photograph of the perforated plate of Example 2 of the disclosure.

FIG. 5B is a SEM microstructure photograph of the porous material of Example 2 of the disclosure.

### DETAILED DESCRIPTION OF DISCLOSED EMBODIMENTS

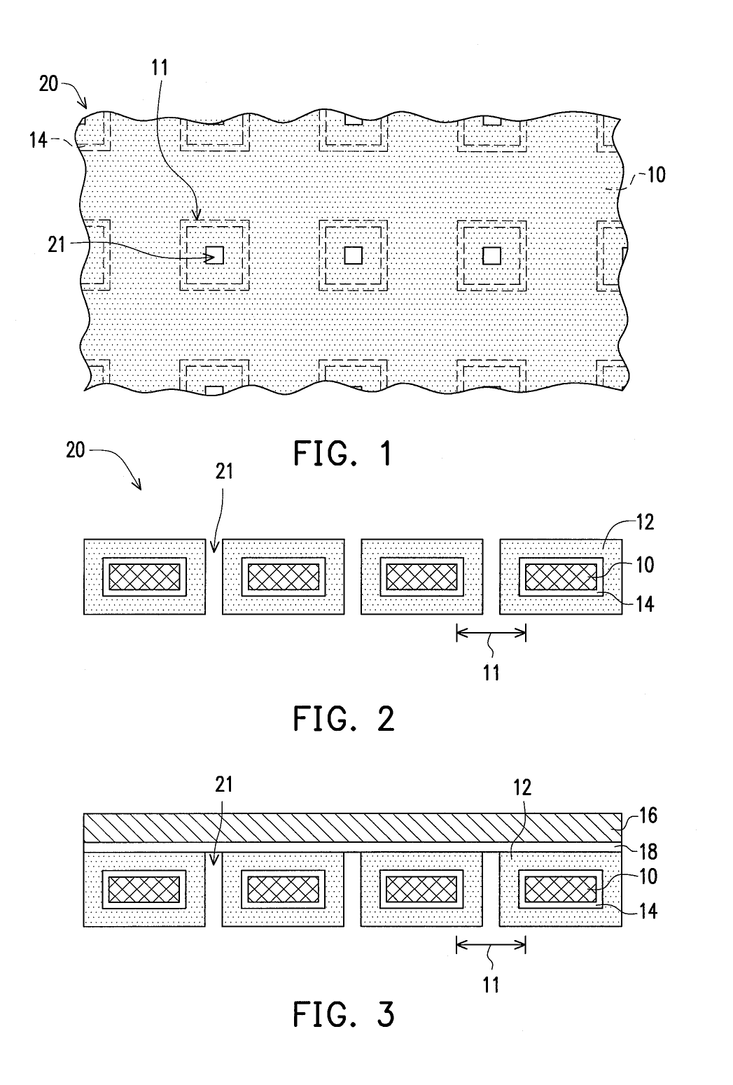

FIG. 1 is a top view illustrating a porous media according to an embodiment of the disclosure. FIG. 2 is a schematic cross-sectional view illustrating a porous media according to an embodiment of the disclosure.

As shown in FIG. 1, a metal mesh 10 is provided. The metal mesh 10 is formed by interlacing a plurality of metal wires, so that a plurality of holes 11 are formed among the metal wires. An area of each of the holes 11 is between 1 μm² to 10,000 m², and an area error between the holes 11 is less than 5%. The metal mesh may be a weaving net or a thin plate with holes. According to an embodiment in which the metal mesh 10 is a weaving net, a method of weaving the weaving net includes a plain weave, a twilled weave, a twilled Dutch weave, or a plain overlapping weave. According to an embodiment in which the metal mesh 10 is a thin plate with holes, the thin plate with holes may be made by stamping or electrical discharge machining. In an embodiment, the holes 11 of the metal mesh 10 have identical and fixed shapes and are arranged in an order. A shape of the holes 11 is, for example, a circle, a triangle, a quadrangle, a rhombus, a polygon, or any other geometric shape. A material of the metal mesh 10 includes pure metal or an alloy, such as stainless steel, nickel-based metal, or copper-based metal.

As shown in FIG. 2, a metal layer 12 is used to cover the metal wires of the metal mesh 10, so as to form a porous media 20. By controlling the thickness of the metal layer 12, an area of each hole 21 of the porous media 20 may be reduced to 0.01 μm²-1 μm², and an area error between the holes 21 is less than 5%; therefore, a metal mesh originally with larger holes are modified into a porous media with smaller holes after the metal mesh is covered by a metal layer. In an embodiment, the porous media with shrinkage holes may be used as a supporting media of a gas selective membrane, such as a supporting media of hydrogen permeation membrane. In addition, metal of the metal layer 12 and metal of the metal mesh 10 have a solid solubility close to 0 at. % at 700° C. and a barrier property of preventing the interdiffusion between metals; therefore, when a gas selective membrane 16 is applied to the metals, the service life of the gas selective membrane 16 may be prolonged. A material of the metal layer 12 includes pure metal or an alloy. In an embodiment, a material of the metal mesh 10 includes stainless steel; the material of the metal layer 12 includes the pure metal of silver (Ag), copper (Cu), calcium (Ca), strontium (Sr), lanthanum (La), or an alloy thereof. A method of forming the metal layer 12 includes electrochemical plating, electroless plating, hot dipping, physical vapor deposition, or chemical vapor deposition. The maximum thickness of the metal layer 12 is 49% of the hole diameter of the metal mesh 10. Since the error of the thickness of the metal layer 12 is within 5%, the difference between the shape of the holes 21 of the formed porous media 20 and the shape of the holes 11 of the metal mesh 10 is not significant. In other words, the holes 11 of the metal mesh 10 have identical and fixed shapes and are arranged in an order, and the holes 21 of the formed porous media 20 also have identical and fixed shapes and are arranged in an order.

In another embodiment, before the metal layer 12 is formed, a transition layer 14 may be formed around the metal mesh 10 so as to assist in shrinking the holes of the metal mesh 10 and reducing the thickness required by the metal layer 12. A material of the transition layer 14 may be the same as or different from that of the metal mesh 10, but it is different from that of the metal layer 12. Specifically, the material of the transition layer 14 includes pure metal or an alloy, such as a nickel-based alloy. Increasing the thickness of the transition layer 14 may reduce the consumption of the metal layer 12, so as to further reduce the costs.

The porous media 20 of the disclosure may be used as a supporting media of a filter core, a filter net of an air-conditioner, a filter net of a heater, a filter net of an air cleaner, a filter material of an aquarium, an activated carbon fiber media, a gas selective membrane, etc.

FIG. 3 is a schematic cross-sectional view illustrating an inorganic selective membrane according to an embodiment of the disclosure.

As shown in FIG. 3, a gas selective membrane 16 is formed on a surface of the above-mentioned porous media 20. A material of the gas selective membrane 16 includes pure palladium metal and an alloy thereof, pure vanadium metal and an alloy thereof, pure niobium metal and an alloy thereof, pure tantalum metal and an alloy thereof, or the combination thereof. A method of forming the gas selective membrane 16 is, for example, plasma sputtering, magnetron sputtering, flame spraying, electroplating and electroless plating, but is not limited thereto. The thickness of the gas selective membrane 16 is, for example, 1 μm to 50 μm. In an embodiment, a modification layer 18 may be formed before the gas selective membrane 16 is formed. The modification layer 18 can ensure great attachment property between the porous material and the gas selective membrane 16. A material of the modification layer 18 is, for example, metal oxide, including aluminum metal oxide, magnesium metal oxide, or nickel metal oxide. The thickness of the modification layer 18 is, for example, 1 μm to 5 μm.

The inorganic selective membrane formed in the above embodiments has high gas flux, and may be used for an inorganic hydrogen selective membrane.

### Example 1

Fabricating a Porous Material of Stainless Steel Net/Nickel/Silver (SSN/Ni/Ag)

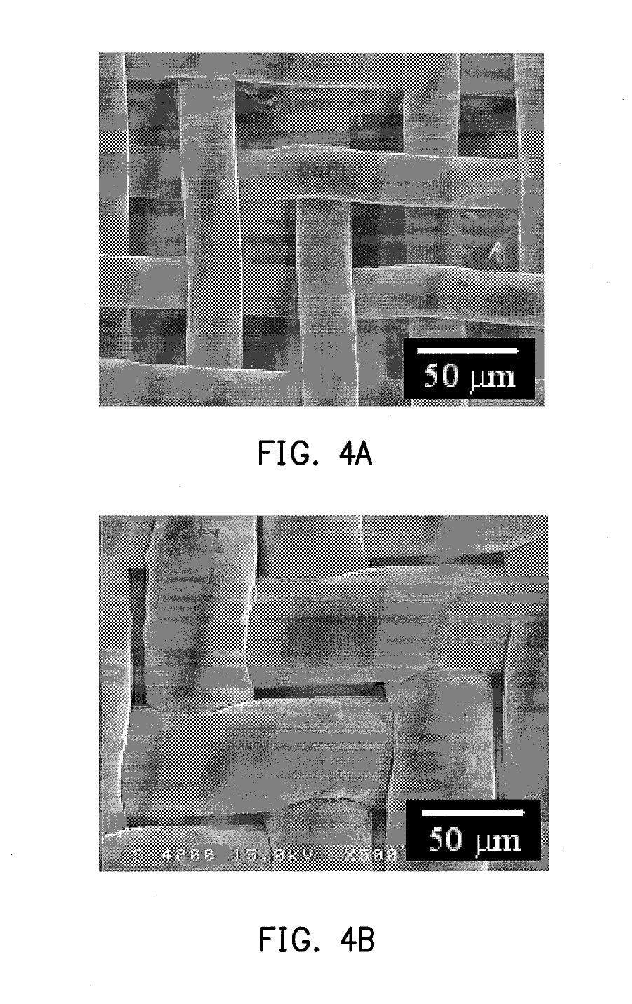

A commercialized material of 316 stainless steel net (mesh No. 400 with a hole size of about 34 μm×34 μm, hereinafter referred to as 316 SSN) is used; its scanning electron microscope (SEM) microscope photograph is shown in FIG. 4A. Through a plating process, silver (Ag) is plated on the surface of 316 SSN to reduce the hole size. The plating process is divided into three steps, including: (1) pre-plating a nickel (Ni) layer with a current density of 0.03 A/cm² at 40° C. for 4 minutes; (2) pre-plating a silver layer with a current density of 0.02 A/cm² at 50° C.-60° C. for 1 minute; (3) plating a silver layer with a current density of 0.02 A/cm² at 50° C.-60° C. for 120 minutes. Through the above plating process, the hole size of 316 SSN may be reduced from 34 m² to 3 μm², and the thickness of the silver layer is about 15 μm. The sample of 316 SSN with a nickel (Ni) layer and a silver layer plated thereon to shrink the holes is referred to as 316 SSN/Ni/Ag, whose SEM microscope photograph is as shown in FIG. 4B.

### Example 2

Fabricating a Porous Material of Stainless Steel Perforated Plate/Nickel/Silver

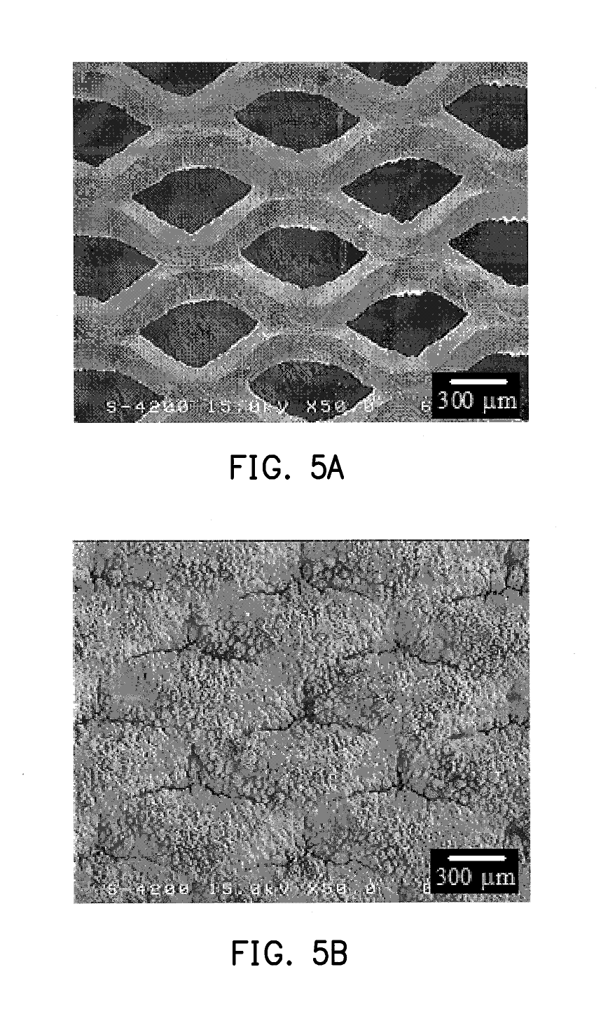

A 304 stainless steel perforated plate is used; its SEM microscope photograph is as shown in FIG. 5A. Through a plating process, silver (Ag) is plated on a surface of 304 stainless steel perforated plate to reduce the hole size. The plating process is divided into three steps, including: (1) pre-plating a nickel (Ni) layer with a current density of 0.03 A/cm² at 40° C. for 4 minutes; (2) pre-plating a silver layer with a current density of 0.02 A/cm² at 50° C.-60° C. for 1 minute; (3) plating a silver layer with a current density of 0.03 A/cm² at 50° C.-60° C. for 30 minutes. Through the above plating process, the hole diameter of 304 perforated plate may be reduced from 600 μm×300 μm to 3 μm-10 μm², and the thickness (along the short axis direction) of the silver layer is about 145 μm-149 μm. The SEM microscope photograph of 304 perforated plate is as shown in FIG. 5B.

### Measuring the Gas Flux

The helium (He) flux of 316 SSN/Ni/Ag of Example 1 is measured at a normal temperature and under different pressure differences. The method of measuring the helium (He) flux refers to the method disclosed in “Preparation of thin Pd membrane on porous stainless steel tubes modified by a two-step method” in INTERNATIONAL JOURNAL OF HYDROGEN ENERGY, volume 35 (2010), pages 6303-6310. The test result obtained through adopting the method proposed in the literature shows that the average He flux of 316 SSN/Ni/Ag of Example 1 reaches 40,000 Nm³/m²·h·atm. Under the same testing conditions, the helium (He) flux of 316 porous stainless steel (316 PSS) is only about 200 Nm³/m²·h·atm. In other words, the average helium (He) flux of 316 SSN/Ni/Ag of Example 1 is 200 times of the helium (He) flux of 316 PSS.

Testing the ability of Silver (Ag) in Suppressing Interdiffusion at a High Temperature

316 SSN/Ni/Ag of Example 1 is used as a supporting material of a hydrogen permeation membrane, and a palladium (Pd) metal layer is formed thereon as a sample of the hydrogen permeation membrane of 316 SSN/Ni/Ag/Pd. After 500 hours of heat treatment under the hydrogen positive pressure of 5 kPa and at 500° C. (generally, the actual hydrogen permeation operation temperature of a hydrogen permeation membrane is about 400° C.-450° C.), the sample is analyzed with an Energy Dispersive X-ray Analyzer (EDS). The result shows that no metal elements of iron (Fe), chromium (Cr), and nickel (Ni) was detected in the Ag layer, which indicates that silver may suppress effectively the diffusion of iron (Fe), chromium (Cr), nickel (Ni) from stainless steel materials to a gas selective membrane (the palladium metal layer) and does not affect hydrogen permeation efficiency. In addition, there is interdiffusion between parts of palladium and silver, and the presence of silver in palladium may increase the flux of hydrogen gas.

### Calculating Cost of Fabricating 316 SSN/Ni/Ag

After estimation, the cost of fabricating 316 SSN/Ni/Ag of Example 1 is only ¼ of the cost of fabricating 316 PSS, i.e., US$2,500/m². By increasing the thickness of the transition layer-the nickel (Ni) plated layer, the consumption of silver (Ag) may be reduced so as to further reduce the cost.

Based on the above, in the method of fabricating a porous media of the disclosure, a metal layer covers a metal mesh with holes of fixed shapes, so as to obtain holes with uniform distribution and uniform size; the size of the holes may be controlled by adjusting the thickness of the covering metal layer. The fabricating process is simple; both the materials and the fabricating process used are advantageous in their low costs. The covering metal layer may prevent interdiffusion of the porous media at a high temperature and may prolong the service life of a gas selective membrane. Therefore, the porous media of the disclosure has high helium flux and interdiffusion resistance at a high temperature and may be made with low costs and applied as a supporting media of an inorganic hydrogen selective membrane.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A method of fabricating a porous media, comprising:
providing a metal mesh, wherein the metal mesh is formed by interlacing a plurality of metal wires, so that a plurality of first holes are formed among the metal wires, an area of each of the first holes is 1 μm² to 10,000 μm², and an area error between the first holes is less than 5%; and
covering the metal wires of the metal mesh with a metal layer, so as to form the porous media with a plurality of second holes, wherein by controlling a thickness of the metal layer, an area of each of the second holes of the porous media is 0.01 μm² to 1 μm², and an area error between the second holes is less than 5%.

2. The method of fabricating the porous media according to claim 1, wherein the first holes in the metal mesh have identical and fixed shapes.

3. The method of fabricating the porous media according to claim 1, wherein the metal mesh is a weaving net or a thin plate with holes.

4. The method of fabricating the porous media according to claim 1, wherein the metal mesh is a weaving net, and a method of weaving the weaving net comprises a plain weave, a twilled weave, a twilled Dutch weave, or a plain overlapping weave.

5. The method of fabricating the porous media according to claim 1, wherein a solid solubility of metals of the metal layer and metals of the metal mesh is close to 0 at. % at 700° C.

6. The method of fabricating the porous media according to claim 1, wherein a material of the metal mesh comprises stainless steel, nickel-based metal, or copper-based metal.

7. The method of fabricating the porous media according to claim 1, wherein a material of the metal mesh comprises pure metal of Ag, Cu, Ca, Sr, and La or an alloy thereof.

8. The method of fabricating the porous media according to claim 1, wherein a method of forming the metal layer comprises electrochemical plating, electroless plating, hot dipping, physical vapor deposition, or chemical vapor deposition.

9. The method of fabricating the porous media according to claim 1, wherein a maximum thickness of the metal layer is 49% of a diameter of the first holes of the metal mesh.

10. The method of fabricating the porous media according to claim 1, further comprising forming a gas selective membrane on the metal layer so as to form the porous media with a gas separation effect.

11. The method of fabricating the porous media according to claim 10, wherein a material of the gas selective membrane comprises palladium metal, vanadium metal, niobium metal, tantalum metal, an alloy thereof, or a combination thereof.

12. The method of fabricating the porous media according to claim 1, further comprising forming a transition layer between the metal mesh and the metal layer.

13. The method of fabricating the porous media according to claim 12, wherein a material of the transition layer is different from a material of the metal layer.

14. A method of fabricating an inorganic selective membrane, comprising:
providing the porous media fabricated according to claim 1, and forming a gas selective membrane on the porous media.

15. The method of fabricating the inorganic selective membrane according to claim 14, wherein a material of the gas selective membrane comprises palladium metal, vanadium metal, niobium metal, tantalum metal, an alloy thereof, or a combination thereof.

16. The method of fabricating the inorganic selective membrane according to claim 14, further comprising forming a modification layer between the porous media and the gas selective membrane.

17. The method of fabricating the inorganic selective membrane according to claim 14, wherein a material of the modification layer comprises aluminum metal oxide, magnesium metal oxide, or nickel metal oxide.
